(19) United States
(12) Patent Application Publication
(10) Pub. No.: US 2026/0173369 A1
(43) Pub. Date: Jun. 18, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Hyukjoon Kwon, Suwon-si (KR); Seokjung Yun, Suwon-si (KR); Yonghyun Lee, Suwon-si (KR); Junghwan Lee, Suwon-si (KR); Byoungil Lee, Suwon-si (KR)

(21) Appl. No.: 19/407,948

(22) Filed: Dec. 3, 2025

(30) Foreign Application Priority Data
Dec. 16, 2024 (KR) 10-2024-0187468

(51) Int. Cl. H10B 41/41; G11C 5/06; G11C 16/04; H10B 41/10; H10B 41/27; H10B 41/35; H10B 43/10; H10B 43/27; H10B 43/35; H10B 43/40; H10D 30/01; H10D 30/68; H10D 30/69

(52) U.S. Cl. CPC H10B 41/41; G11C 5/063; G11C 16/0483; H10B 41/10; H10B 41/27; H10B 41/35; H10B 43/10; H10B 43/27; H10B 43/35; H10B 43/40; H10D 30/689; H10D 30/693; H10D 30/0411; H10D 30/0413

(57) ABSTRACT

An example semiconductor device improves the tilt of an extension region by forming an H- or I-shaped pad connection part in only a portion of the extension region and may have high integration density and excellent electrical characteristics by controlling defects that may be caused by the pad connector in the extension region.

### CROSS-REFERENCE TO RELATED APPLICATION

This application claims priority under 35 U.S.C. § 119 to Korean Patent Application No. 10-2024-0187468, filed on Dec. 16, 2024, in the Korean Intellectual Property Office, the disclosure of which is incorporated by reference herein in its entirety.

### BACKGROUND

To meet high performance and economic feasibility requirements for semiconductor

devices, it is desired to increase the integration density thereof. In particular, the integration density of memory devices is an important factor in determining the economic feasibility of products. The integration density of two-dimensional (2D) memory devices is mainly determined by the area of a memory cell unit and is thus greatly influenced by the level of micropatterning technology. However, the increase in the integration density of 2D memory devices may be limited because expensive equipment is used to form micropatterns and the area of a chip die is limited. Therefore, there is a demand for technology for increasing the integration density of 2D memory devices and vertical memory device technology having a three-dimensional (3D) structure.

### SUMMARY

The present disclosure relates to a semiconductor device capable of improving the tilt of an extension region by forming an H- or I-shaped pad connection part in only a portion of the extension region and having high integration density and excellent electrical characteristics by controlling a defect that may be caused by the pad connector in the extension region and an electronic system including the semiconductor device.

The present disclosure is not limited to what is mentioned above and will be clearly understood by those skilled in the art from the descriptions below.

In some implementations, a semiconductor device includes a substrate having an extension region and a cell region, the extension region having a first region closest to the cell region in a first horizontal direction, a third region farthest from the cell region, and a second region between the first region and the third region, gate electrodes stacked and separated from each other on the substrate in a vertical direction and forming first and second stack structures, isolation regions passing through the first and second stack structures in the vertical direction and extending lengthwise in the first horizontal direction, channel structures passing through the first and second stack structures in the vertical direction in the cell region, and first and second contact plugs passing through the first and second stack structures in the vertical direction in the extension region, wherein the first stack structure includes first pad regions and first dummy regions in the extension region, each of the gate electrodes is longer than another gate electrode thereabove and is connected to one of the first contact plugs in each of the first pad regions, each of the first dummy regions is at one side of one of the first pad regions and is separated from the first contact plugs, the second stack structure includes second pad regions and second dummy regions in the extension region, each of the gate electrodes is longer than another gate electrode thereabove and is connected to one of the second contact plugs in each of the second pad regions, each of the second dummy regions is at one side of one of the second pad regions and is separated from the second contact plugs, the first pad regions overlap the second dummy regions in the vertical direction, the second pad regions overlap the first dummy regions in the vertical direction, and the isolation regions include a word line cut and a dummy line cut, the word line cut continuously extending in the first horizontal direction in the cell region and the extension region, and the dummy line cut discontinuously extending in the first and third regions of the extension region and continuously extending in the second region of the extension region.

In some implementations, a semiconductor device includes a memory cell structure on a peripheral circuit structure, wherein the peripheral circuit structure includes a first substrate, circuit elements on the first substrate, and lower wiring lines connected to the circuit elements, and the memory cell structure includes a second substrate having an extension region and a cell region, the extension region having a first region closest to the cell region in a first horizontal direction, a third region farthest from the cell region, and a second region between the first region and the third region, gate electrodes stacked and separated from each other on the second substrate in a vertical direction and forming first and second stack structures, interlayer dielectric layers alternately stacked with the gate electrodes, isolation regions passing through the first and second stack structures in the vertical direction and extending lengthwise in the first horizontal direction, channel structures passing through the first and second stack structures in the vertical direction in the cell region, first and second contact plugs passing through the first and second stack structures in the vertical direction in the extension region, extending into the peripheral circuit structure, and connected to the lower wiring lines, and dummy extension structures passing through the first and second stack structures in the vertical direction in the extension region, wherein the first stack structure includes first pad regions and first dummy regions in the extension region, each of the gate electrodes is longer than another gate electrode thereabove and is connected to one of the first contact plugs in each of the first pad regions, each of the first dummy regions is at one side of one of the first pad regions and is separated from the first contact plugs, the second stack structure includes second pad regions and second dummy regions in the extension region, each of the gate electrodes is longer than another gate electrode thereabove and is connected to one of the second contact plugs in each of the second pad regions, each of the second dummy regions is at one side of one of the second pad regions and is separated from the second contact plugs, the first pad regions overlap the second dummy regions in the vertical direction, the second pad regions overlap the first dummy regions in the vertical direction, and the isolation regions include a word line cut and a dummy line cut, the word line cut continuously extending in the first horizontal direction in the cell region and the extension region, and the dummy line cut discontinuously extending in at least one of the first and third regions of the extension region and continuously extending in the second region of the extension region.

In some implementations, an electronic system includes a main substrate, a semiconductor device on the main substrate, and a controller on the main substrate and connected to the semiconductor device, wherein the semiconductor device includes a peripheral circuit structure and a memory cell structure on the peripheral circuit structure, wherein the peripheral circuit structure includes a circuit substrate, a peripheral circuit transistor on the circuit substrate, a lower wiring connected to the peripheral circuit transistor, and a peripheral dielectric layer covering the peripheral circuit transistor and the lower wiring, and the memory cell structure includes a memory substrate having an extension region and a cell region, the extension region having a first region closest to the cell region in a first horizontal direction, a third region farthest from the cell region, and a second region between the first region and the third region, gate electrodes stacked and separated from each other on the memory substrate in a vertical direction and forming first and second stack structures, isolation regions passing through the first and second stack structures in the vertical direction and extending lengthwise in the first horizontal direction, channel structures passing through the first and second stack structures in the vertical direction in the cell region, and first and second contact plugs passing through the first and second stack structures in the vertical direction in the extension region, wherein the first stack structure includes first pad regions and first dummy regions in the extension region, each of the gate electrodes is longer than another gate electrode thereabove and is connected to one of the first contact plugs in each of the first pad regions, each of the first dummy regions is at one side of one of the first pad regions and is separated from the first contact plugs, the second stack structure includes second pad regions and second dummy regions in the extension region, each of the gate electrodes is longer than another gate electrode thereabove and is connected to one of the second contact plugs in each of the second pad regions, each of the second dummy regions is at one side of one of the second pad regions and is separated from the second contact plugs, the first pad regions overlap the second dummy regions in the vertical direction, the second pad regions overlap the first dummy regions in the vertical direction, and the isolation regions include a word line cut and a dummy line cut, the word line cut continuously extending in the first horizontal direction in the cell region and the extension region, and the dummy line cut discontinuously extending in the first and third regions of the extension region and continuously extending in the second region of the extension region.

### BRIEF DESCRIPTION OF THE DRAWINGS

Implementations will be more clearly understood from the following detailed description taken in conjunction with the accompanying drawings.

FIG. 1 is an equivalent circuit diagram of an example of a memory cell array of a semiconductor device.

FIG. 2 is a plan view illustrating example elements of a semiconductor device.

FIG. 3 is an example enlarged perspective view of a region AA in FIG. 2.

FIG. 4 is an example cross-sectional view taken along line I-I′ in FIG. 2.

FIG. 5 is an example cross-sectional view taken along line II-II′ in FIG. 2.

FIG. 6 is an example cross-sectional view taken along line III-III′ in FIG. 2.

FIG. 7 is an example enlarged perspective view of a region BB in FIG. 5.

FIGS. 8, 9, and 10 are diagrams illustrating example elements of a semiconductor device.

FIGS. 11, 12, 13, 14, 15, 16, 17, and 18 are diagrams illustrating example sequential stages in a method of manufacturing a semiconductor device.

FIG. 19 is a diagram of an example of an electronic system including a semiconductor device.

FIG. 20 is a perspective view of an example of an electronic system including a semiconductor device.

FIG. 21 is a cross-sectional view of an example of a semiconductor package including a semiconductor device.

### DETAILED DESCRIPTION

Hereinafter, implementations are described in detail with reference to the accompanying drawings.

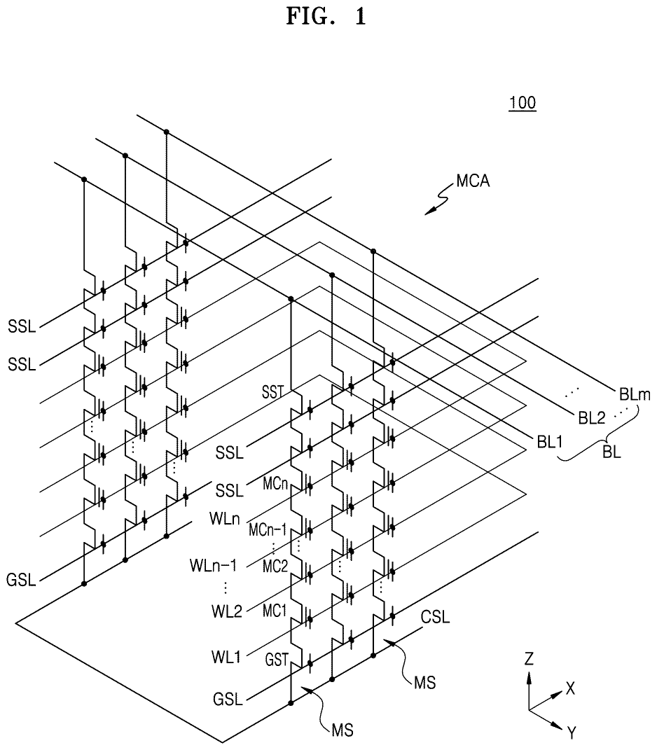

FIG. 1 is an equivalent circuit diagram of an example of a memory cell array of a semiconductor device.

FIG. 1 illustrates an equivalent circuit of a vertical NAND flash memory device having a vertical channel structure.

In a semiconductor device 100, a memory cell array MCA may include a plurality of memory cell strings MS. The memory cell array MCA may include a plurality of bit lines BL or BL1 to BLm, a plurality of word lines WL or WL1 to WLn, at least one string select line SSL, at least one ground select line GSL, a common source line CSL.

The memory cell strings MS may be between the common source line CSL and the bit lines BL. Although it is illustrated in FIG. 1 that each of the memory cell strings MS includes two string select lines SSL, the present disclosure is not limited thereto. For example, each of the memory cell strings MS may include one string select line SSL.

Each of the memory cell strings MS may include a string select transistor SST, a ground select transistor GST, and a plurality of memory cell transistors MC1 to MCn. A drain region of the string select transistor SST may be connected to its corresponding one among the bit lines BL, and a source region of the ground select transistor GST may be connected to the common source line CSL. Respective source regions of a plurality of ground select transistors GST may be connected in common to the common source line CSL.

The string select transistor SST may be connected to a string select line SSL, and a ground select transistor GST may be connected to the ground select line GSL. The memory cell transistors MC1 to MCn may be respectively connected to the word lines WL1 to WLn.

Elements of the semiconductor device 100 including the memory cell array MCA described above are described in detail below.

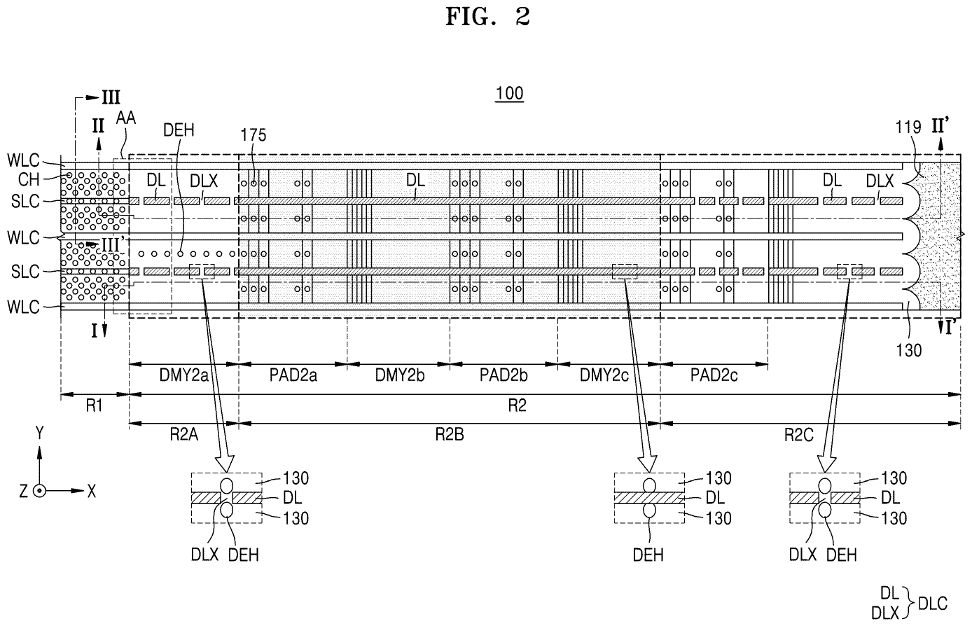

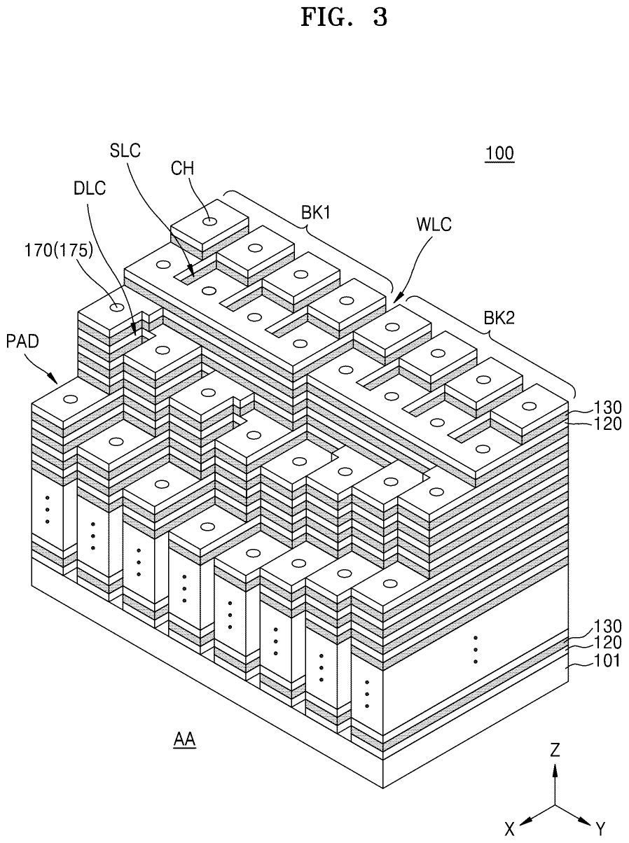

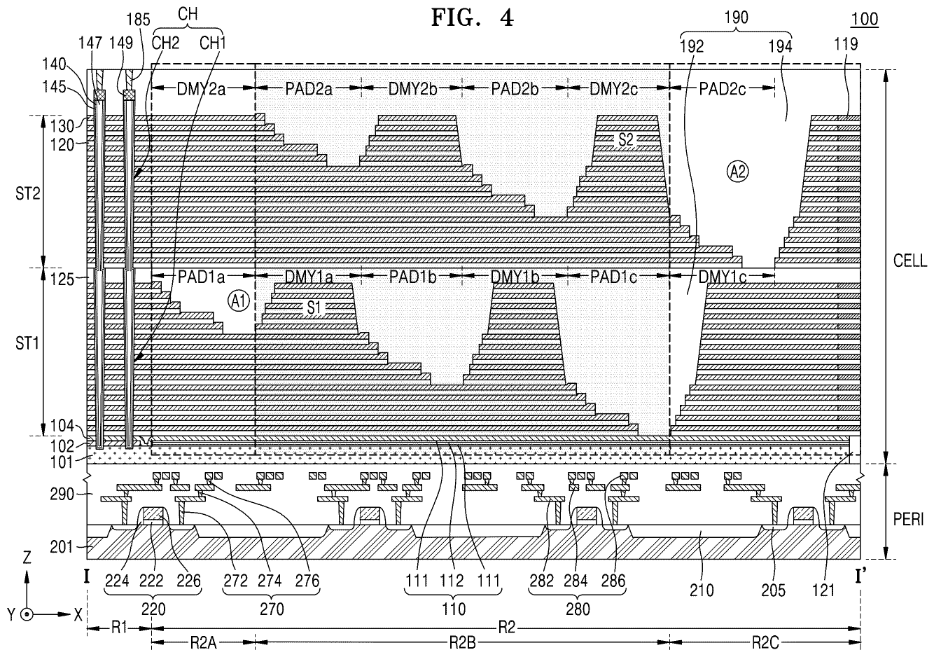

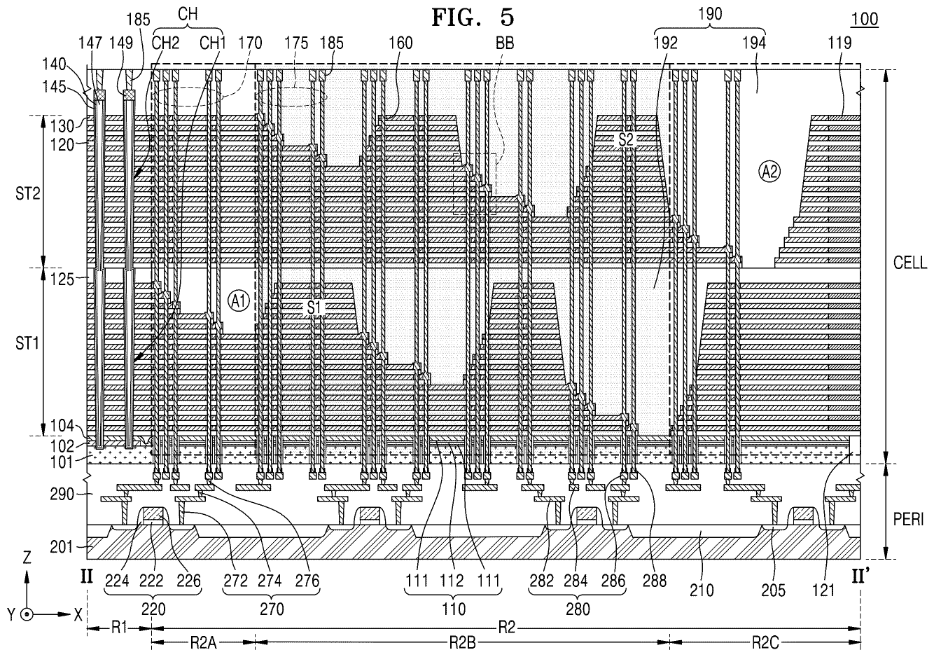

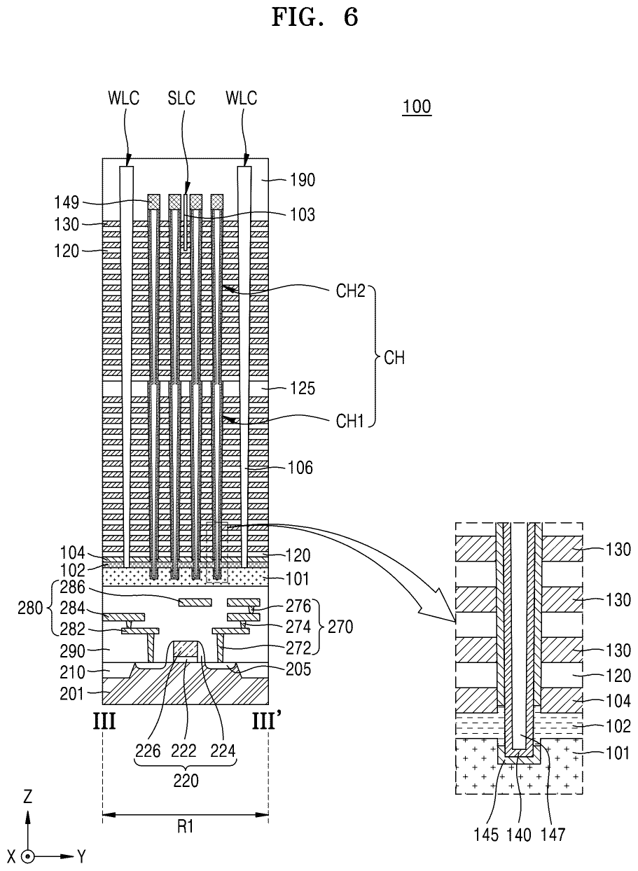

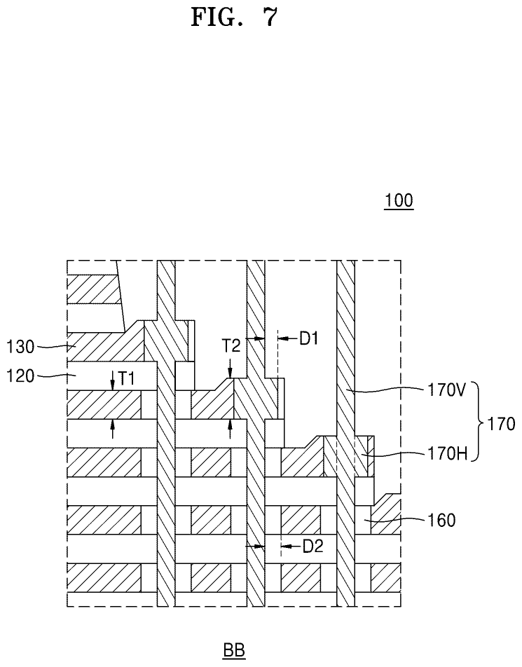

FIG. 2 is a plan view illustrating example elements of the semiconductor device 100. FIG. 3 is an example enlarged perspective view of a region AA in FIG. 2. FIG. 4 is an example cross-sectional view taken along line I-I′ in FIG. 2. FIG. 5 is an example cross-sectional view taken along line II-II′ in FIG. 2. FIG. 6 is an example cross-sectional view taken along line III-III′ in FIG. 2. FIG. 7 is an example enlarged perspective view of a region BB in FIG. 5.

Referring to FIGS. 2 to 7, the semiconductor device 100 may include a peripheral circuit structure PERI including a first substrate 201 and a memory cell structure CELL including a second substrate 101.

In some implementations, the memory cell structure CELL may be arranged above the peripheral circuit structure PERI. In some implementations, the memory cell structure CELL may be arranged below the peripheral circuit structure PERI.

The peripheral circuit structure PERI may include the first substrate 201, impurity regions 205 and isolation layers 210, which are arranged inside the first substrate 201, and circuit elements 220, lower contact plugs 270, lower wiring lines 280, and a peripheral dielectric layer 290, which are arranged above the first substrate 201.

An active region may be defined in the first substrate 201 by the isolation layers 210. The impurity regions 205 may be arranged in a portion of the active region. The first substrate 201 may include a semiconductor material, e.g., a Group IV semiconductor, a Group III-V compound semiconductor, or a Group II-VI compound semiconductor. The first substrate 201 may be provided as a bulk wafer or an epitaxial layer.

The circuit elements 220 may include planar transistors. Each of the circuit elements 220 may include a circuit gate dielectric layer 222, a spacer layer 224, and a circuit gate electrode 226. The impurity regions 205 may be arranged, as source/drain regions, in the first substrate 201 and respectively at opposite sides of the circuit gate electrode 226.

The lower contact plugs 270 and the lower wiring lines 280 may form a lower wiring structure that is electrically connected to the circuit elements 220 and the impurity regions 205. The lower contact plugs 270 may include first to third lower contact plugs 272, 274, and 276 sequentially arranged from the first substrate 201. The lower wiring lines 280 may include first to third lower wiring lines 282, 284, and 286 sequentially arranged from the first substrate 201. The lower contact plugs 270 and the lower wiring lines 280 may include a conductive material, e.g., tungsten (W), copper (Cu), or aluminum (Al). Pad layers 288 may be respectively arranged on the third lower wiring lines 286.

The peripheral dielectric layer 290 may be arranged on the first substrate 201 to cover the circuit elements 220. The peripheral dielectric layer 290 may include a dielectric material and a plurality of dielectric layers.

The memory cell structure CELL may include the second substrate 101 having a cell region R1 and an extension region R2, gate electrodes 130 stacked on the second substrate 101 and forming first and second stack structures ST1 and ST2, interlayer dielectric layers 120 alternately stacked with the gate electrodes 130 on the second substrate 101, channel structures CH passing through the first and second stack structures ST1 and ST2, first and second contact plugs 170 and 175 connected to the gate electrodes 130 of the first and second stack structures ST1 and ST2, and contact dielectric layers 160 respectively surrounding the first and second contact plugs 170 and 175.

In the memory cell structure CELL, the cell region R1 may correspond to a region in which the gate electrodes 130 are vertically stacked and the channel structures CH are arranged, i.e., a region in which memory cells are arranged, and the extension region R2 may correspond to a region, in which the gate electrodes 130 extend in different lengths, and may be provided to electrically connect the memory cells to the peripheral circuit structure PERI.

The memory cell structure CELL may further include a substrate dielectric layer 121, first and second horizontal conductive layers 102 and 104 below the gate electrodes 130 in the cell region R1, horizontal dielectric layers 110 below the gate electrodes 130 in the extension region R2, residual dielectric layers 119 outside the gate electrodes 130, upper contacts 185 respectively on the channel structures CH and the first and second contact plugs 170 and 175, and a cell dielectric layer 190 covering the gate electrodes 130.

The memory cell structure CELL may include isolation regions. The isolation regions may include word line cuts WLC passing through the first and second stack structures ST1 and ST2 and extending across the cell region R1 and the extension region R2, upper line cuts SLC passing through a portion of the second stack structure ST2 in the cell region R1, and dummy line cuts DLC passing through the first and second stack structures ST1 and ST2 in the extension region R2. These are described in detail below.

The second substrate 101 may have a plate shape and function as a portion of a common source line of the semiconductor device 100. The second substrate 101 may be provided as a polycrystalline semiconductor layer, such as a polysilicon layer, or an epitaxial layer.

The first and second horizontal conductive layers 102 and 104 may be sequentially stacked on the second substrate 101 in the cell region R1. The first horizontal conductive layer 102 may not extend to the extension region R2 of the second substrate 101, and the second horizontal conductive layer 104 may extend to the extension region R2. The first horizontal conductive layer 102 may be directly connected to a channel layer 140. The second horizontal conductive layer 104 may be in contact with the second substrate 101 in some regions in which the first horizontal conductive layer 102 and the horizontal dielectric layer 110 are not arranged.

The horizontal dielectric layer 110 may be arranged on the second substrate 101 in at least a portion of the extension region R2. The horizontal dielectric layer 110 may include first and second horizontal dielectric layers 111 and 112 alternately stacked on the second substrate 101 in the extension region R2. The horizontal dielectric layer 110 may include silicon oxide, silicon nitride, silicon carbide, or silicon oxynitride. The first horizontal dielectric layers 111 and the second horizontal dielectric layer 112 may include different dielectric materials.

The substrate dielectric layer 121 may extend in a vertical direction Z in the extension region R2 and may pass through the second substrate 101, the horizontal dielectric layer 110, and the second horizontal conductive layer 104. The substrate dielectric layer 121 may surround the first and second contact plugs 170 and 175. Accordingly, the first and second contact plugs 170 and 175 respectively connected to the gate electrodes 130 may be electrically separated from each other.

The gate electrodes 130 may be stacked on the second substrate 101 vertically spaced apart from each other and may form the first and second stack structures ST1 and ST2. For example, the gate electrodes 130 may form the first and second stack structures ST1 and ST2 together with the interlayer dielectric layers 120. The gate electrodes 130 may include a metal material, e.g., tungsten (W). Alternatively, the gate electrodes 130 may include polysilicon or metal silicide. The gate electrodes 130 may be stacked vertically spaced apart from each other in the cell region R1 and my extend from the cell region R1 to the extension region R2 in different lengths, thereby forming a stepped structure in a portion of the extension region R2.

The gate electrodes 130 may form a stepped structure in a first horizontal direction X and a second horizontal direction Y. Specifically, the gate electrodes 130 may be divided into first and second blocks BK1 and BK2 by a word line cut WLC in the first horizontal direction X. In the extension region R2, the gate electrodes 130 may be arranged in a stepped structure in the first horizontal direction X. Four gate electrodes 130 that are sequentially stacked may have the same length in the first horizontal direction X and may be arranged in a stepped structure in the second horizontal direction Y. Accordingly, pad regions PAD of the first block BK1 and the second block BL2 may have a mirror symmetric structure. The pad regions PAD may form first pad regions PAD1a, PAD1b, and PAD1c and second pad regions PAD2a, PAD2b, and PAD2c, according to a location where the pad regions PAD are arranged.

The first and second stack structures ST1 and ST2 may be sequentially stacked on the second substrate 101 in the vertical direction Z. The first and second stack structures ST1 and ST2 may be constituted of the gate electrodes 130 and the interlayer dielectric layers 120, which are alternately stacked with each other.

The first stack structure ST1 may have the first pad regions PAD1a, PAD1b, and PAD1c and first dummy regions DMY1a, DMY1b, and DMY1c in the extension region R2. The first pad regions PAD1a, PAD1b, and PAD1c and the first dummy regions DMY1a, DMY1b, and DMY1c may be alternately arranged in the first horizontal direction X.

The second stack structure ST2 may have the second pad regions PAD2a, PAD2b, and PAD2c and second dummy regions DMY2a, DMY2b, and DMY2c in the extension region R2. The second pad regions PAD2a, PAD2b, and PAD2c and the second dummy regions DMY2a, DMY2b, and DMY2c may be alternately arranged in the first horizontal direction X.

The first pad regions PAD1a, PAD1b, and PAD1c may respectively shift from the second pad regions PAD2a, PAD2b, and PAD2c and may thus not overlap the second pad regions PAD2a, PAD2b, and PAD2c in the vertical direction Z. In other words, the first pad regions PAD1a, PAD1b, and PAD1c may respectively overlap the second dummy regions DMY2a, DMY2b, and DMY2c in the vertical direction Z, and the second pad regions PAD2a, PAD2b, and PAD2c may respectively overlap the first dummy regions DMY1a, DMY1b, and DMY1c in the vertical direction Z.

In the first pad regions PAD1a, PAD1b, and PAD1c and the second pad regions PAD2a, PAD2b, and PAD2c, the gate electrodes 130 may have a longer length away from the top gate electrode 130 and may thus be respectively connected to the first and second contact plugs 170 and 175. In the first dummy regions DMY1a, DMY1b, and DMY1c and the second dummy regions DMY2a, DMY2b, and DMY2c, each of the gate electrodes 130 may not be directly connected to one of the first and second contact plugs 170 and 175 and may be separated from one of the first and second contact plugs 170 and 175 by one of the contact dielectric layers 160.

The heights of the gate electrodes 130 in the first pad regions PAD1a, PAD1b, and PAD1c and the second pad regions PAD2a, PAD2b, and PAD2c may decrease away from the cell region R1 in the first horizontal direction X. Each of the first dummy regions DMY1a, DMY1b, and DMY1c and the second dummy regions DMY2a, DMY2b, and DMY2c may include the same of gate electrodes 130 as or a greater number of gate electrodes 130 than an adjacent one of the first pad regions PAD1a, PAD1b, and PAD1c and the second pad regions PAD2a, PAD2b, and PAD2c.

The first and second stack structures ST1 and ST2 may have corresponding shapes of the gate electrodes 130 in the extension region R2. For example, the shape or profile of gate electrodes 130 in each of the first pad regions PAD1a, PAD1b, and PAD1c may be the same as that of gate electrodes 130 in a corresponding one of the second pad regions PAD2a, PAD2b, and PAD2c. The second pad region PAD2a closest to the cell region R1 may be shifted by the length of the first pad region PAD1a in the first horizontal direction X, and accordingly, the other second pad regions PAD2b and PAD2c and some second dummy regions DMY2b and DMY2c may also be shifted.

In each of the first pad regions PAD1a, PAD1b, and PAD1c, the first contact plugs 170 respectively connected to the gate electrodes 130 may be respectively connected to the lower wiring lines 280 of the peripheral circuit structure PERI. The first pad regions PAD1a, PAD1b, and PAD1c may include a flat region in which the bottommost gate electrodes 130 extend lengthwise without a step.

In each of the second pad regions PAD2a, PAD2b, and PAD2c, the second contact plugs 175 respectively connected to the gate electrodes 130 may be respectively connected to the lower wiring lines 280 of the peripheral circuit structure PERI. The second pad regions PAD2a, PAD2b, and PAD2c may include a flat region in which the bottommost gate electrodes 130 extend lengthwise without a step.

Each of the interlayer dielectric layers 120 may be between two adjacent gate electrodes 130. Like the gate electrodes 130, the interlayer dielectric layers 120 may be arranged on the second substrate 101 to be spaced apart from each other in the vertical direction Z. The interlayer dielectric layers 120 may include a dielectric material, such as silicon oxide or silicon nitride.

The residual dielectric layers 119 may be respectively at the same level as the gate electrodes 130 and may have the same thickness as the gate electrodes 130. Each of the residual dielectric layers 119 may be arranged at an outer side of its corresponding one of the gate electrodes 130, and a side surface of each of the residual dielectric layers 119 may be in contact with a side surface of its corresponding one of the gate electrodes 130. The residual dielectric layers 119 may have a width that is the same as or different from the width of the substrate dielectric layer 121 below the residual dielectric layers 119. The residual dielectric layers 119 may include a different dielectric material than the interlayer dielectric layers 120.

The word line cuts WLC may pass through the gate electrodes 130 in the cell region R1 and the extension region R2 and may extend in the first horizontal direction X. The word line cuts WLC may parallel with each other. Each of the word line cuts WLC may extend lengthwise across the cell region R1 and the extension region R2. Each of the word line cuts WLC may entirely pass through all the gate electrodes 130 stacked on the second substrate 101 and may be connected to the second substrate 101. Isolation dielectric layers 106 including a dielectric material may be respectively arranged in the word line cuts WLC.

The upper line cuts SLC may extend in the first horizontal direction X in the cell region R1. Each of the upper line cuts SLC may pass through some upper ones of the gate electrodes 130 in the cell region R1. For example, each of the upper line cuts SLC may divide three upper gate electrodes 130. However, the number of gate electrodes 130 divided by the upper line cuts SLC may vary. Upper isolation dielectric layers 103 including a dielectric material may be respectively arranged in the upper line cuts SLC.

The dummy line cuts DLC may extend in the first horizontal direction X in the extension region R2. The dummy line cuts DLC may pass through the gate electrodes 130 and may extend in the first horizontal direction X. The dummy line cuts DLC may be parallel with each other. Each of the dummy line cuts DLC may entirely pass through all the gate electrodes 130 stacked on the second substrate 101.

In the semiconductor device 100 of the present disclosure, each of the dummy line cuts DLC may continuously or discontinuously extend according to its location in the extension region R2.

The extension region R2 may be divided into a first region R2A from the start of the extension region R2 to the start of the first dummy regions DMY1a, DMY1b, and DMY1c (i.e., the start of a start region S1), a second region R2B from the start of the first dummy regions DMY1a, DMY1b, and DMY1c (i.e., the start of the start region S1) to the end of the second dummy regions DMY2a, DMY2b, and DMY2c (i.e., the end of an end region S2), and a third region R2C from the end the second dummy regions DMY2a, DMY2b, and DMY2c (i.e., the end of the end region S2) to the end of the extension region R2.

In other words, the extension region R2 may be divided into the first region R2A from the start of the extension region R2 to the end of the first pad region PAD1a (i.e., the end of a start region A1), which comes first among the first pad regions PAD1a, PAD1b, and PAD1c, the second region R2B from the end of the first pad region PAD1a (i.e., the end of the start region A1) to the start of the second pad region PAD2c (i.e., the start of an end region A2), which comes last among the second pad regions PAD2a, PAD2b, and PAD2c, and the third region R2C from the start of the second pad region PAD2c (i.e., the start of the end region A2) to the end of the extension region R2.

Specifically, each of the dummy line cuts DLC may be configured to discontinuously extend in the first and third regions R2A and R2C of the extension region R2 and continuously extend in the second region R2B of the extension region R2. For this configuration, each of the dummy line cuts DLC may include dummy line parts DL and pad connection parts DLX, which are alternately arranged with each other in the first horizontal direction X, in the first and third regions R2A and R2C of the extension region R2. In the second region R2B of the extension region R2, each of the dummy line cuts DLC may not include the pad connection parts DLX and may include a single dummy line part DL extending lengthwise in the first horizontal direction X.

The dummy line parts DL may separate the gate electrodes 130 from each other in the second horizontal direction Y, and the pad connection parts DLX may connect the gate electrodes 130 to each other in the second horizontal direction Y. In other words, one of the pad connection parts DLX and gate electrodes 130 around one pad connection part DLX may have an H or I shape in a plan view. The dummy line parts DL may include a dielectric material.

The channel structures CH may each form a single memory cell string and may be separated from one another in row and columns in the cell region R1. The channel structures CH may be arranged in a lattice pattern or a zigzag form. Each of the channel structures CH may have a pillar shape and an inclined sidewall such that each channel structure CH becomes narrower toward the second substrate 101.

Each of the channel structures CH may include a first and second channel structures CH1 and CH2. Each of the channel structures CH may have a shape in which the first channel structure CH1 passing through the first stack structure ST1 is connected to the second channel structure CH2 passing through the second stack structure ST2.

Each of the channel structures CH may include the channel layer 140, a gate dielectric layer 145, a channel buried dielectric layer 147, and a channel pad 149, which are arranged in a channel hole. The channel layer 140 may have a ring shape surrounding the channel buried dielectric layer 147 inside the channel layer 140. A lower portion of the channel layer 140 may be connected to the first horizontal conductive layer 102. The channel layer 140 may include polysilicon or monocrystalline silicon. The gate dielectric layer 145 may be between the channel layer 140 and each of the gate electrodes 130. Although not shown, the gate dielectric layer 145 may include a tunneling layer, a charge storage layer, and a blocking layer, which are sequentially formed from the channel layer 140. The channel pad 149 may be arranged in an upper portion of only the second channel structure CH2.

The channel layer 140, the gate dielectric layer 145, and the channel buried dielectric layer 147 may continue from the first channel structure CH1 to the second channel structure CH2. An upper interlayer dielectric layer 125 may be between the first channel structure CH1 and the second channel structure CH2, i.e., between the first and second stack structures ST1 and ST2.

Supports having a different structure than the channel structures CH may be separately arranged in the extension region R2. For example, dummy extension structures DEH may be arranged in the extension region R2. Although the dummy extension structures DEH are shown in only a portion of the extension region R2 in the drawings, the dummy extension structures DEH may be formed throughout the extension region R2. The dummy extension structures DEH may a shape that is the same as or similar to the shape of the channel structures CH. However, unlike the channel structures CH, the dummy extension structures DEH may not form memory cell strings but may only serve as support structures.

In the first and third regions R2A and R2C of the extension region R2, each of the dummy line cuts DLC may include the dummy line parts DL and the pad connection parts DLX, which are alternately arranged with each other in the first horizontal direction X. Accordingly, the dummy extension structures DEH passing through the pad connection parts DLX may be arranged between the dummy line parts DL. Differently, the pad connection parts DLX may not be arranged in the second region R2B of the extension region R2, and a dummy line part DL may extend lengthwise in the first horizontal direction X such that the dummy line part DL may cut a portion of each of dummy extension structures DEH adjacent to each other in the second horizontal direction Y.

In the extension region R2, each of the first and second contact plugs 170 and 175 may pass through the topmost gate electrode 130 and contact dielectric layers 160 below the topmost gate electrode 130 and may be connected to the topmost gate electrode 130. In the first pad regions PAD1a, PAD1b, and PAD1c, the first contact plugs 170 may be respectively connected to the gate electrodes 130 of the first stack structure ST1. In the second pad regions PAD2a, PAD2b, and PAD2c, the second contact plugs 175 may be respectively connected to the gate electrodes 130 of the second stack structure ST2.

The first and second contact plugs 170 and 175 may pass through at least a portion of the cell dielectric layer 190 and may respectively connected to gate electrodes 130 of which the top surfaces are exposed through steps. Each of the first and second contact plugs 170 and 175 may be directly connected to a gate electrode 130 in a region in which the thickness of the gate electrode 130 increases. Below the gate electrodes 130, the first and second contact plugs 170 and 175 may pass through the second substrate 101, the second horizontal conductive layer 104, and the horizontal dielectric layer 110 and may be connected to the lower wiring lines 280 of the peripheral circuit structure PERI. The first and second contact plugs 170 and 175 may be separated from the second substrate 101, the second horizontal conductive layer 104, and the horizontal dielectric layer 110 by the substrate dielectric layer 121.

Each of the first contact plugs 170 may include a vertical extension part 170V, which extends in the vertical direction Z, and a horizontal extension part 170H, which horizontally extends from the vertical extension part 170V and is contact with a gate electrode 130. The vertical extension part 170V may have a cylindrical shape having a width decreasing toward the second substrate 101. The horizontal extension part 170H may be arranged around the vertical extension part 170V and may extend a first dimension D1 from the side surface of the vertical extension part 170V. The first dimension D1 may be less than a second dimension D2 of each of the contact dielectric layers 160. The second contact plugs 175 may have substantially the same shape as the first contact plugs 170. For example, the first and second contact plugs 170 and 175 may include tungsten (W), copper (Cu), or aluminum (Al).

The contact dielectric layers 160 may between the first and second contact plugs 170 and 175 and the gate electrodes 130 except for the gate electrodes 130 connected to the first and second contact plugs 170 and 175. The inner surfaces of the contact dielectric layers 160 may surround the first and second contact plugs 170 and 175, and the outer surfaces of the contact dielectric layers 160 may be surrounded by the gate electrodes 130. Due to the contact dielectric layers 160, each of the first and second contact plugs 170 and 175 may be electrically connected to one of the gate electrodes 130 and electrically disconnected from the other gate electrodes 130. The contact dielectric layers 160 may include a dielectric material, such as silicon oxide, silicon nitride, or silicon oxynitride.

The upper contacts 185 may form a part of an upper wiring structure electrically connected to memory cells of the memory cell structure CELL. The upper contacts 185 may be respectively connected to the channel structures CH and the first and second contact plugs 170 and 175.

The cell dielectric layer 190 may include a first cell dielectric layer 192 covering the first stack structure ST1 and a second cell dielectric layer 194 covering the second stack structure ST2. In some implementations, each of the first and second cell dielectric layers 192 and 194 may include a plurality of dielectric layers.

In general, a selected one of the pad connection parts DLX and gate electrodes 130 around the selected pad connection part DLX may have an H or I shape in the semiconductor device 100 in a plan view and thus serve as a support that improves the tilt of the extension region R2. However, because the dummy extension structures DEH passing through the pad connection parts DLX are arranged between the dummy line part DL, the width of the gate electrodes 130 may decrease such that Joule's heat due to the flow of current increases above a limit, causing a problem (hereinafter, referred to as a first defect) in which peripheral structures deteriorate. In particular, the first dummy regions DMY1a, DMY1b, and DMY1c and the second dummy regions DMY2a, DMY2b, and DMY2c, in which the gate electrodes 130 are arranged in a relatively flat shape, are more vulnerable with respect to the first defect. However, when the pad connection parts DLX are all removed to prevent the first defect, structures serving as supports in the extension region R2 may be decreased, causing another problem (hereinafter, referred to as a second defect) in which the extension region R2 tilts.

To prevent both the first and second defects, in the semiconductor device 100 of the present disclosure, the dummy line cuts DLC may be configured to discontinuously extend in the first and third regions R2A and R2C of the extension region R2 and continuously extend in the second region R2B of the extension region R2.

Specifically, in the semiconductor device 100 of the present disclosure, each of the dummy line cuts DLC may include the dummy line part DL and the pad connection parts DLX, which are alternately arranged with each other in the first horizontal direction X in the first and third regions R2A and R2C of the extension region R2, and each of the dummy line cuts DLC may not include the pad connection parts DLX and may include one dummy line part DL extending lengthwise in the first horizontal direction X in the second region R2B of the extension region R2.

In other words, the semiconductor device 100 of the present disclosure may not include the pad connection parts DLX in a region from the start region S1 of the first dummy regions DMY1a, DMY1b, and DMY1c to the end region S2 of the second dummy regions DMY2a, DMY2b, and DMY2c, thereby preventing the first defect, wherein the region from the start region S1 to the end region S2 are between the start region A1 of the first pad regions PAD1a, PAD1b, and PAD1c and the end region A2 of the second pad regions PAD2a, PAD2b, and PAD2c. The semiconductor device 100 of the present disclosure may prevent the second defect by including the pad connection parts DLX in the extension region R2 except for the region from the start region S1 to the end region S2.

Consequently, the semiconductor device 100 of the present disclosure may improve the tilt of the extension region R2 by including the pad connection parts DLX having an H or I shape in only a portion of the extension region R2 and may have high integration density and excellent electrical characteristics by controlling Joule's heat that may occur due to the pad connection parts DLX in the extension region R2.

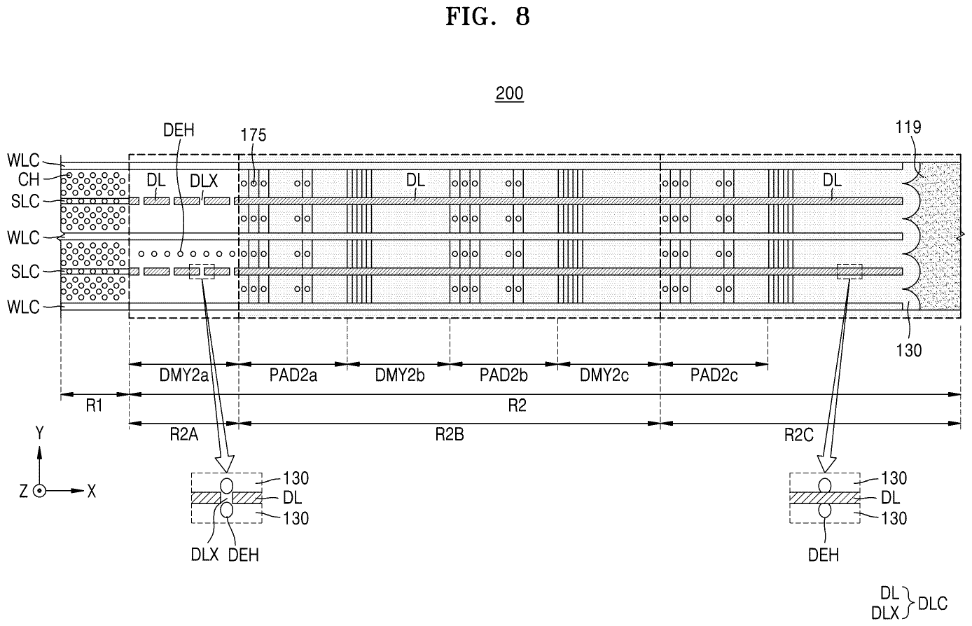

FIGS. 8, 9, and 10 are diagrams illustrating example elements of a semiconductor device.

The elements of semiconductor devices 200, 300, and 400 and the materials of the elements described below are mostly and substantially the same as or similar to those described above with reference to FIGS. 2 to 7. Thus, for convenience of description, descriptions below will be focused on differences from the semiconductor device 100 described above.

Referring to FIG. 8, in the semiconductor device 200, the dummy line cuts DLC may be configured to discontinuously extend in the first region R2A of the extension region R2 and continuously extend in the second and third regions R2B and R2C of the extension region R2.

For this configuration in the semiconductor device 200, each of the dummy line cuts DLC in the first region R2A of the extension region R2 may include dummy line parts DL and pad connection parts DLX, which are alternately arranged with each other in the first horizontal direction X. In the second and third regions R2B and R2C of the extension region R2, each of the dummy line cuts DLC may not include the pad connection parts DLX and may have a shape in which a single dummy line part DL extends lengthwise in the first horizontal direction X.

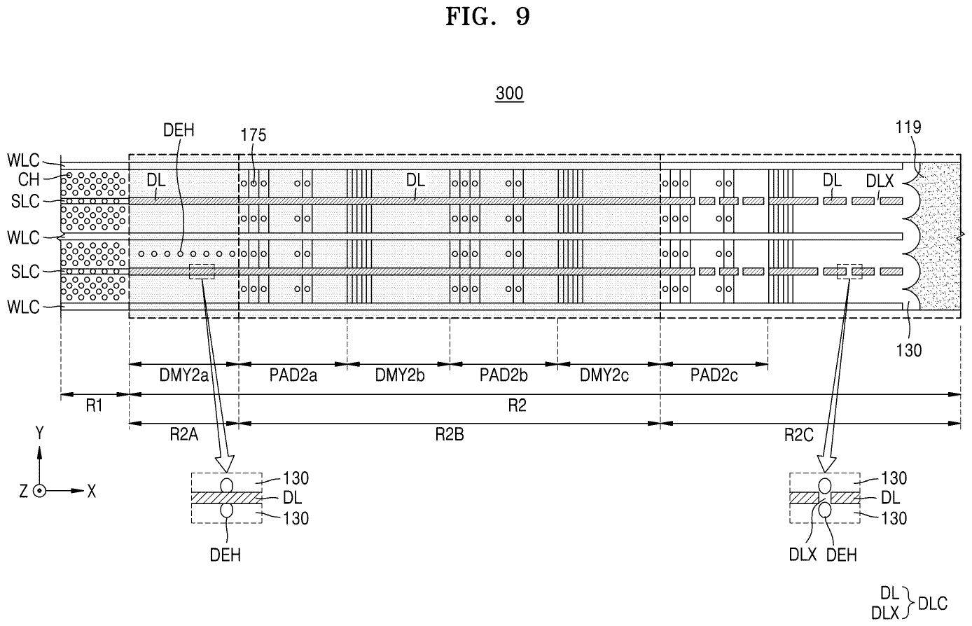

Referring to FIG. 9, in the semiconductor device 300, the dummy line cuts DLC may be configured to discontinuously extend in the third region R2C of the extension region R2 and continuously extend in the first and second regions R2A and R2B of the extension region R2.

For this configuration in the semiconductor device 300, each of the dummy line cuts DLC in the third region R2C of the extension region R2 may include dummy line parts DL and pad connection parts DLX, which are alternately arranged with each other in the first horizontal direction X. In the first and second regions R2A and R2B of the extension region R2, each of the dummy line cuts DLC may not include the pad connection parts DLX and may have a shape in which a single dummy line part DL extends lengthwise in the first horizontal direction X.

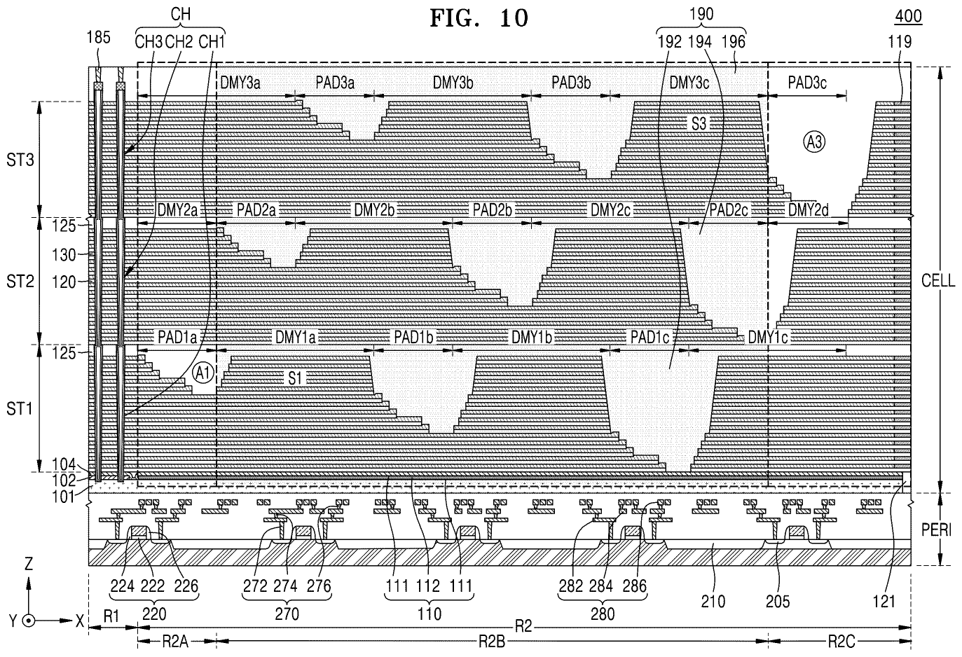

Referring to FIG. 10, in the semiconductor device 400, the gate electrodes 130 of the memory cell structure CELL may form first to third stack structures ST1, ST2, and ST3, and channel structures CH may have a shape in which first to third channel structures CH1, CH2, and CH3 are stacked.

In the semiconductor device 400, the third stack structure ST3 may have third pad regions PAD3a, PAD3b, and PAD3c and third dummy regions DMY3a, DMY3b, and DMY3c in the extension region R2. The third pad regions PAD3a, PAD3b, and PAD3c and the third dummy regions DMY3a, DMY3b, and DMY3c may be alternately arranged with each other in the first horizontal direction X. The second stack structure ST2 may further include a second dummy region DMY2d at the rightmost side thereof.

The first pad regions PAD1a, PAD1b, and PAD1c, the second pad regions PAD2a, PAD2b, and PAD2c, and the third pad regions PAD3a, PAD3b, and PAD3c may be shifted from one another and may thus not overlap one another in the vertical direction Z. The first pad regions PAD1a, PAD1b, and PAD1c may overlap some second dummy regions DMY2a, DMY2b, and DMY2c and the third dummy regions DMY3a, DMY3b, and DMY3c in the vertical direction Z. The second pad regions PAD2a, PAD2b, and PAD2c may overlap the first dummy regions DMY1a, DMY1b, and DMY1c and the third dummy regions DMY3a, DMY3b, and DMY3c in the vertical direction Z. The third pad regions PAD3a, PAD3b, and PAD3c may overlap the first dummy regions DMY1a, DMY1b, and DMY1c and some second dummy regions DMY2b, DMY2c, and DMY2d in the vertical direction Z.

In the semiconductor device 400, the dummy line cuts DLC (see FIG. 2) may continuously or discontinuously extend according to locations in the extension region R2.

The extension region R2 may be divided into the first region R2A from the start of the extension region R2 to the start of the first dummy regions DMY1a, DMY1b, and DMY1c (i.e., the start of the start region S1), the second region R2B from the start of the first dummy regions DMY1a, DMY1b, and DMY1c (i.e., the start of the start region S1) to the end of the third dummy regions DMY3a, DMY3b, and DMY3c (i.e., the end of an end region S3), and the third region R2C from the end the third dummy regions DMY3a, DMY3b, and DMY3c (i.e., the end of the end region S3) to the end of the extension region R2.

Specifically, each of the dummy line cuts DLC may include the dummy line parts DL (see FIG. 2) and the pad connection parts DLX (see FIG. 2), which are alternately arranged with each other in the first horizontal direction X, in the first and third regions R2A and R2C of the extension region R2. In the second region R2B of the extension region R2, each of the dummy line cuts DLC may not include the pad connection parts DLX and may include a single dummy line part DL extending lengthwise in the first horizontal direction X.

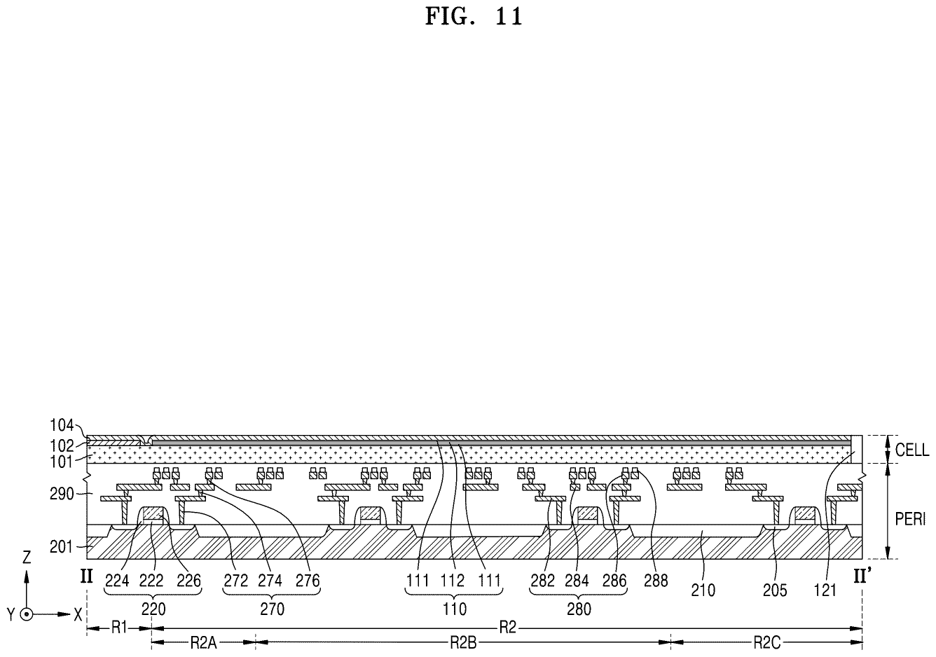

FIGS. 11, 12, 13, 14, 15, 16, 17, and 18 are diagrams illustrating example sequential stages in a method of manufacturing a semiconductor device.

In some implementations, the order of operations may be different from the order in which the operations are described. For instance, two operations described as being performed sequentially may be substantially performed simultaneously or in a reverse order.

Referring to FIG. 11, the peripheral circuit structure PERI including the circuit elements 220 and lower wiring structures on the first substrate 201 may be formed, and the second substrate 101, the horizontal dielectric layer 110, the second horizontal conductive layer 104, and the substrate dielectric layer 121 may be formed on the peripheral circuit structure PERI.

A process of manufacturing the peripheral circuit structure PERI is obvious to one of ordinary skill in the art, and thus, detailed descriptions thereof are omitted.

The second substrate 101 may be formed on the peripheral circuit structure PERI. For example, the second substrate 101 may include polysilicon. Polysilicon of the second substrate 101 may include impurities.

The first and second horizontal dielectric layers 111 and 112 of the horizontal dielectric layer 110 may be alternately stacked on the second substrate 101. The second horizontal conductive layer 104 may be formed on the horizontal dielectric layer 110 and may be in contact with the second substrate 101 in a portion from which the horizontal dielectric layer 110 is removed.

The substrate dielectric layer 121 may be formed through the second substrate 101. The substrate dielectric layer 121 may be formed by removing portions of the second substrate 101, the horizontal dielectric layer 110, and the second horizontal conductive layer 104 and filling the removed portions with a dielectric material.

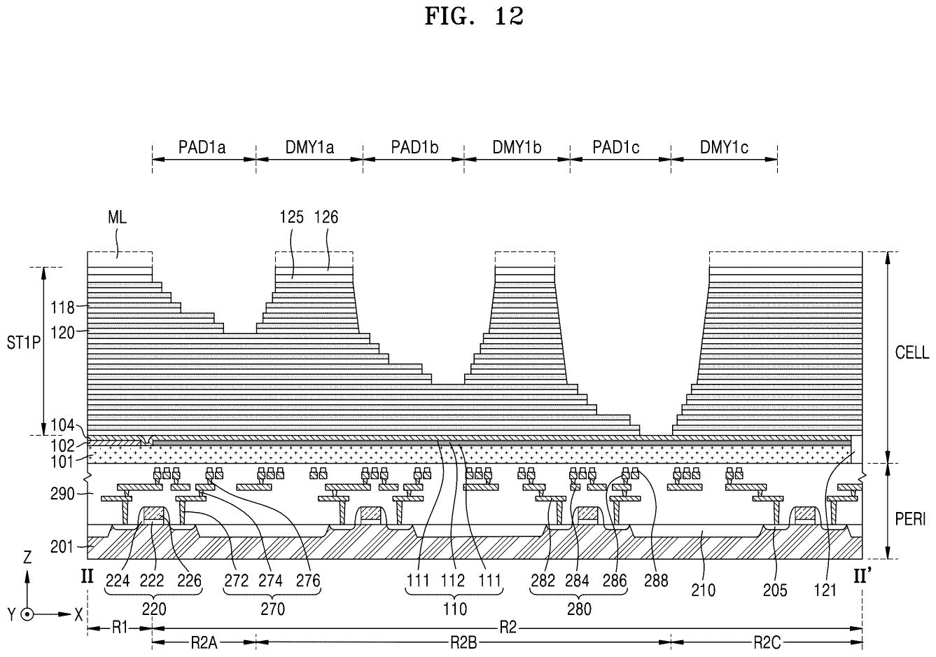

Referring to FIG. 12, a first preliminary stack structure ST1P may be formed on the second horizontal conductive layer 104 by alternately stacking sacrificial dielectric layers 118 and interlayer dielectric layers 120. The first preliminary stack structure ST1P may be formed in a stepped structure.

The upper interlayer dielectric layer 125 may be formed relatively thick at the top of the first preliminary stack structure ST1P, and an etch stop layer 126 may be formed on the upper interlayer dielectric layer 125. The sacrificial dielectric layers 118 may be replaced with gate electrodes 130 in a subsequent process.

The sacrificial dielectric layers 118 may include a material which is different from the material of the interlayer dielectric layers 120 and has an etch selectivity with respect to the interlayer dielectric layers 120. The etch stop layer 126 may protect a lower structure when the stepped structure is formed.

Subsequently, a mask layer ML may be formed, and the exposed portion of the first preliminary stack structure ST1P may be etched. A process of trimming the mask layer ML and a process of etching the first preliminary stack structure ST1P may be repeatedly performed. When the process of trimming the mask layer ML is repeatedly performed, the area of the exposed portion of the first preliminary stack structure ST1P may gradually increase.

According to the process of etching the first preliminary stack structure ST1P, the first pad region PAD1a, the first dummy region DMY1a, the first pad region PAD1b, the first dummy region DMY1b, the first pad region PAD1c, and the first dummy region DMY1c may be sequentially formed.

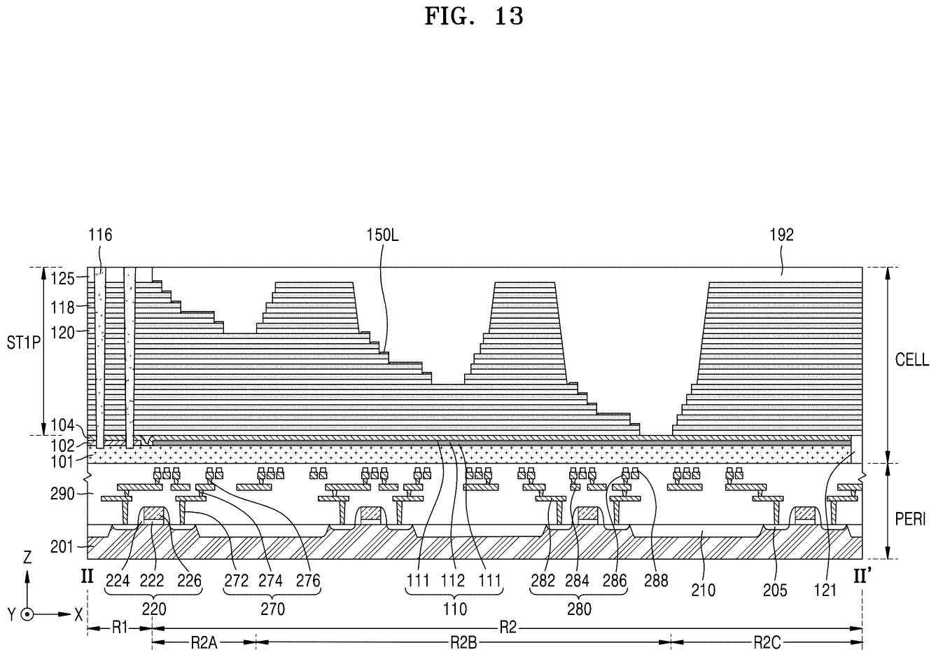

Referring to FIG. 13, a first nitride layer 150L may be formed to cover the top surfaces of exposed sacrificial dielectric layers 118, and a first cell dielectric layer 192 may be formed to cover the first preliminary stack structure ST1P.

Subsequently, channel sacrificial layers 116 may be formed in portions corresponding to the first channel structures CH1 in the cell region R1. The channel sacrificial layers 116 may be formed by forming lower channel holes through the first preliminary stack structure ST1P and respectively forming the channel sacrificial layers 116 in the lower channel holes.

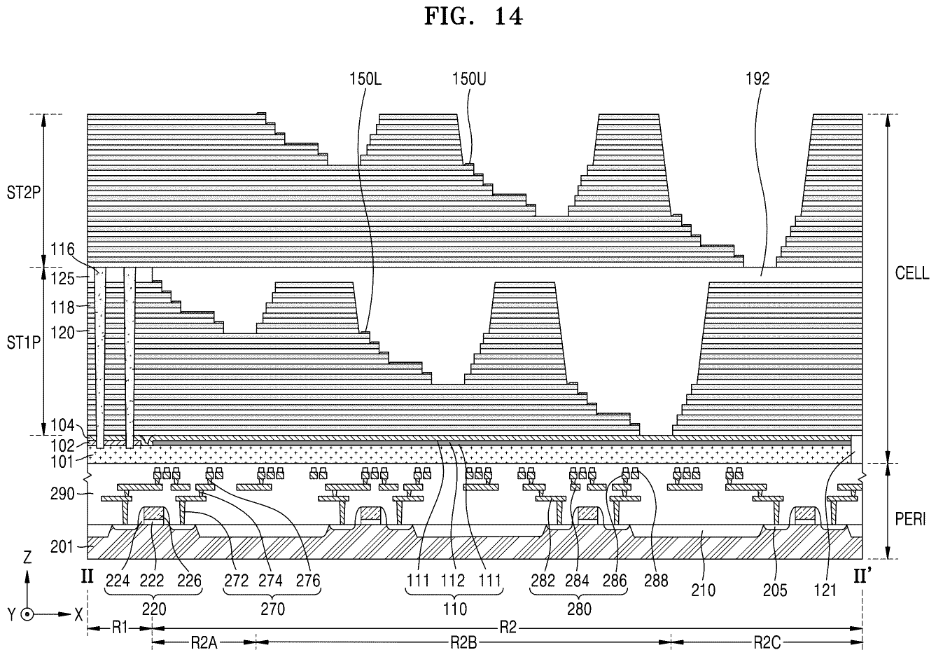

Referring to FIG. 14, a second preliminary stack structure ST2P may be formed on the first preliminary stack structure ST1P by alternately stacking sacrificial dielectric layers 118 and interlayer dielectric layers 120. After the second preliminary stack structure ST2P is formed in a stepped structure, a second nitride layer 150U may be formed.

In the present process, substantially the same process performed on the first preliminary stack structure ST1P described above may be performed on the second preliminary stack structure ST2P. The second nitride layer 150U may be formed on some exposed top surfaces of the sacrificial dielectric layers 118.

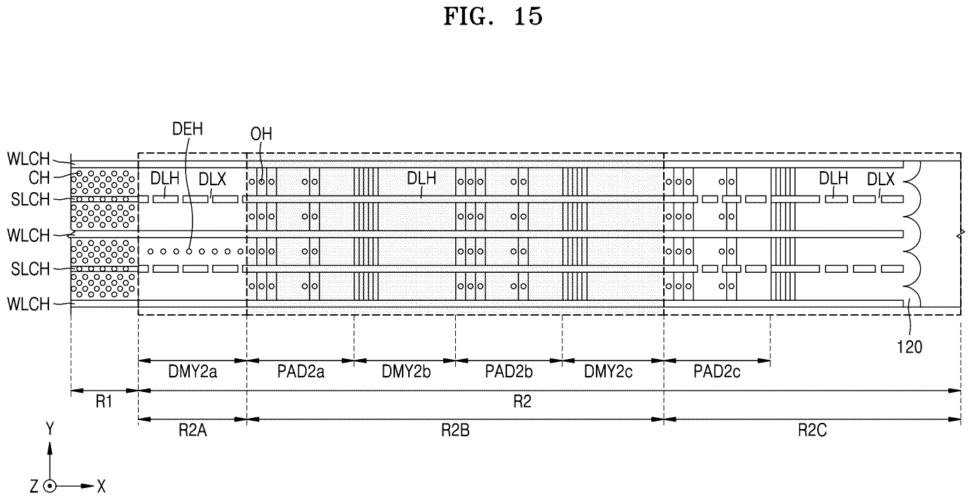

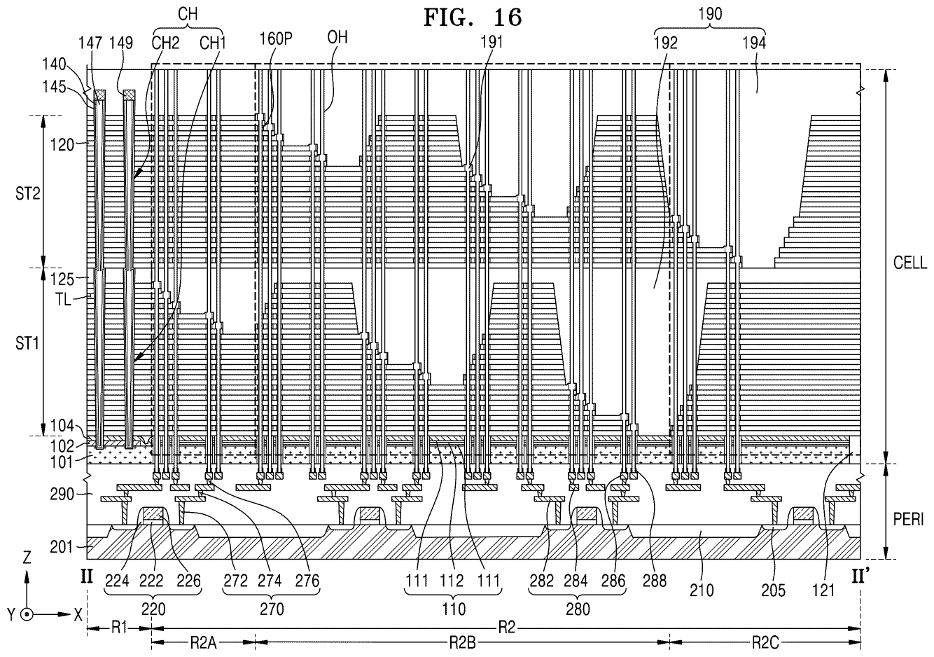

Referring to FIGS. 15 and 16, after channel structures CH and dummy extension structures DEH are formed, contact openings OH may be formed.

The channel structures CH may be formed by forming upper channel holes through the second preliminary stack structure ST2P in the cell region R1, forming entire channel holes by removing the channel sacrificial layers 116, and filling in the entire channel holes. Specifically, the channel structures CH may be formed by forming the gate dielectric layer 145, the channel layer 140, the channel buried dielectric layer 147, and the channel pad 149 in each of the entire channel holes. Similarly, the dummy extension structures DEH may be formed in the extension region R2.

The contact openings OH may define regions in which the first and second contact plugs 170 and 175 are respectively formed. Before the contact openings OH are formed, the second cell dielectric layer 194 may be formed to cover the channel structures CH. The contact openings OH may each have a cylindrical shape and may extend to the peripheral circuit structure PERI through the first and second preliminary stack structures ST1P and ST2P and the substrate dielectric layer 121. The contact openings OH may expose the pad layers 288 on the lower wiring lines 280.

Subsequently, word line cut openings WLCH may be respectively formed in the positions of the word line cuts WLC to extend to the second substrate 101 through the sacrificial dielectric layers 118 and the interlayer dielectric layers 120. Upper line cut openings SLCH may be respectively formed in the positions of the upper line cuts SLC to extend through some upper ones of the sacrificial dielectric layers 118 and some upper ones of the interlayer dielectric layers 120. Dummy line openings DLH may be respectively formed in the positions of the dummy line parts DL to discontinuously extend through the sacrificial dielectric layers 118 and the interlayer dielectric layers 120.

Subsequently, all the sacrificial dielectric layers 118 may be removed by an etching process. Accordingly, tunnels TL may be formed between the interlayer dielectric layers 120.

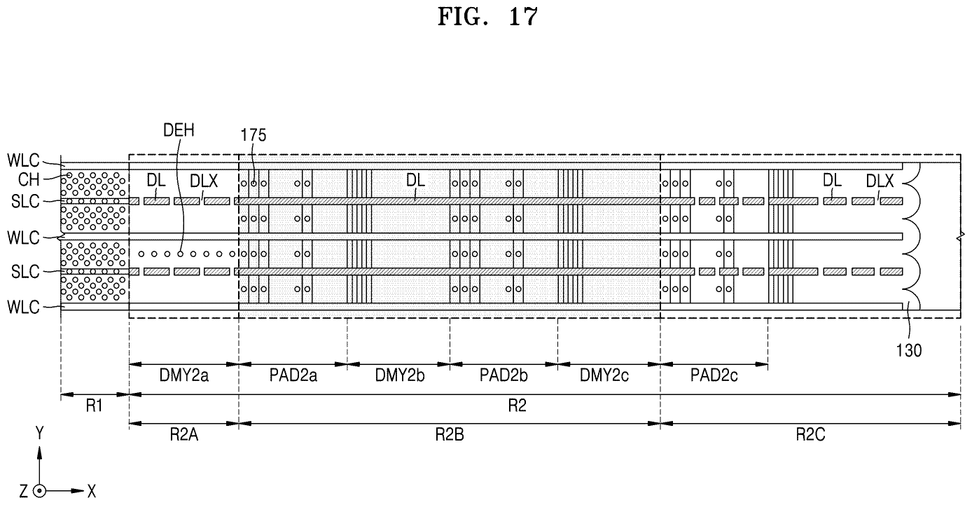

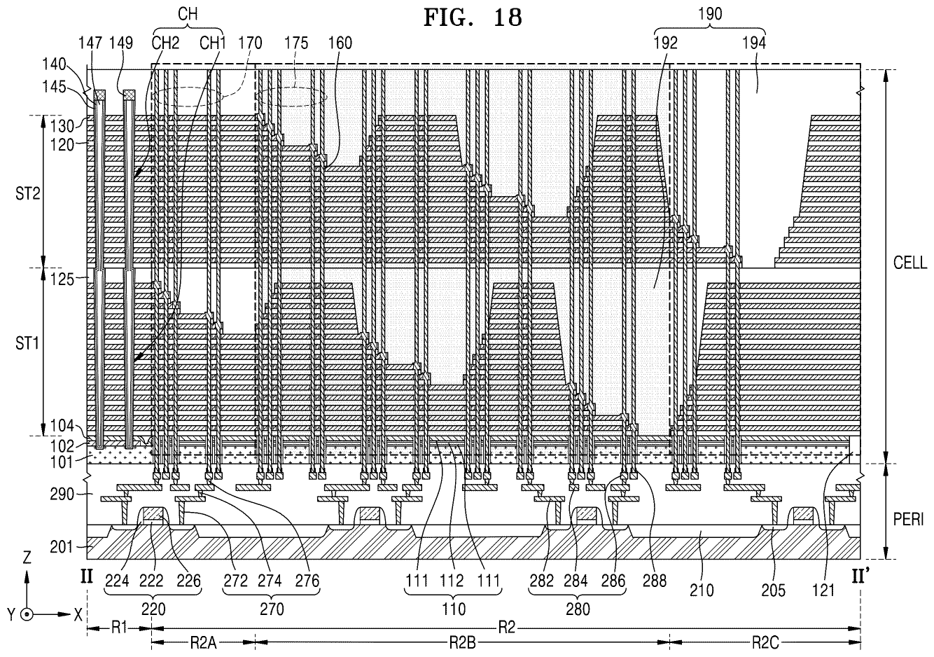

Referring to FIGS. 17 and 18, the gate electrodes 130 may be formed by filling the tunnels TL with a conductive material. The contact dielectric layers 160 may be formed by partially removing preliminary contact dielectric layers 160P after removing vertical sacrificial layers 191.

Before the gate electrodes 130 are formed, a portion of the gate dielectric layer 145, which vertically extends through the gate electrodes 130, may be formed. Accordingly, the first and second stack structures ST1 and ST2 may be formed.

After the gate electrodes 130 are formed, the word line cuts WLC, the upper line cuts SLC, and the dummy line parts DL may be formed by filling the word line cut openings WLCH, the upper line cut openings SLCH, and the dummy line openings DLH with a dielectric material.

Subsequently, the first and second contact plugs 170 and 175 may be formed by filling the contact openings OH with a conductive material. Specifically, the pad layers 288 may be partially removed from the bottoms of the contact openings OH to expose the third lower wiring lines 286, and then, the conductive material may be formed.

The first and second contact plugs 170 and 175 may be simultaneously formed by the same process and thus have the same structure. Each of the first contact plugs 170 may include a horizontal extension part connected to one of the gate electrodes 130 of the first stack structure ST1, and each of the second contact plugs 175 may include a horizontal extension part connected to one of the gate electrodes 130 of the second stack structure ST2

Referring back to FIG. 5, the upper contacts 185 may be formed to be respectively connected to the tops of the first and second contact plugs 170 and 175 and the tops of the channel structures CH, thereby manufacturing the semiconductor device 100.

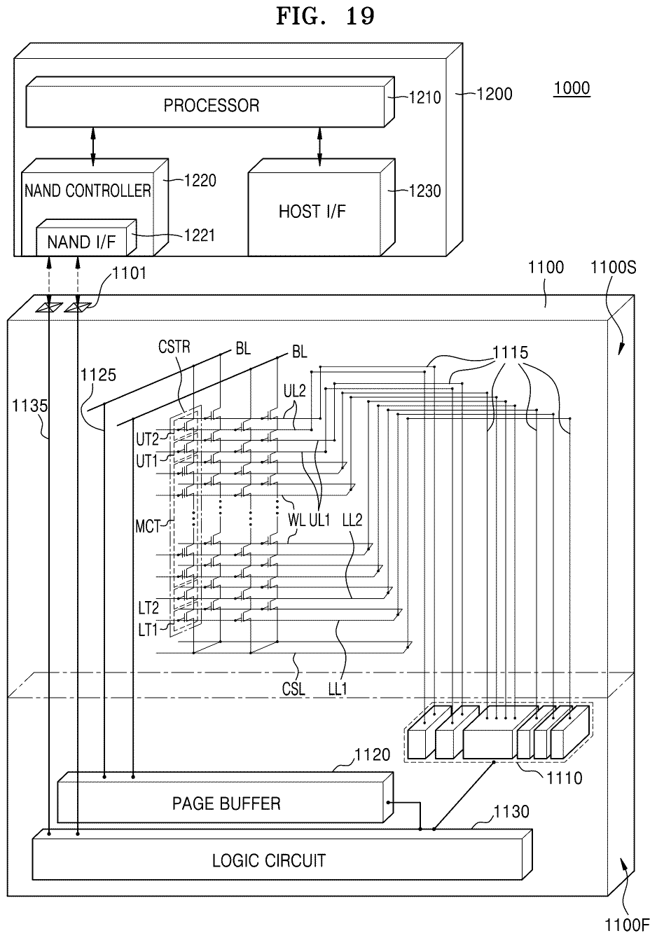

FIG. 19 is a diagram of an example of an electronic system including a semiconductor device.

Referring to FIG. 19, an electronic system 1000 may include a semiconductor device 1100 and a controller 1200 electrically connected to the semiconductor device 1100.

The electronic system 1000 may correspond to a storage device including one or more semiconductor devices 1100 or an electronic device including the storage device. For example, the electronic system 1000 may correspond to any one of a solid state drive (SSD) device, a universal serial bus (USB) device, a computing system, a medical device, and a communication device, each of which includes at least one semiconductor device 1100.

The semiconductor device 1100 may include a non-volatile vertical memory device. For example, the semiconductor device 1100 may include a NAND flash memory device including at least one of the semiconductor devices 100, 200, 300, and 400 described with reference to FIGS. 2 to 10. The semiconductor device 1100 may include a first structure 1100F and a second structure 1100S on the first structure 1100F. In some implementations, the first structure 1100F may be next to the second structure 1100S.

The first structure 1100F may correspond to a peripheral circuit structure, which includes a decoder circuit 1110, a page buffer 1120, and a logic circuit 1130. The second structure 1100S may correspond to a memory cell structure, which includes a bit line BL, a common source line CSL, a plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the memory cell strings CSTR may include lower transistors LT1 and LT2 near the common source line CSL, upper transistors UT1 and UT2 near the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may vary with implementations.

In some implementations, the upper transistors UT1 and UT2 may include a string select transistor, and the lower transistors LT1 and LT2 may include a ground select transistor. The first and second gate lower lines LL1 and LL2 may respectively correspond to respective gate electrodes of the lower transistors LT1 and LT2. Each of the word lines WL may correspond to a gate electrode of a memory cell transistor MCT. The first and second gate upper lines UL1 and UL2 may respectively correspond to respective gate electrodes of the upper transistors UT1 and UT2.

The common source line CSL, the first and second gate lower lines LL1 and LL2, the word lines WL, and the first and second gate upper lines UL1 and UL2 may be electrically connected to the decoder circuit 1110 through a plurality of first interconnection lines 1115 extending from the first structure 1100F to the second structure 1100S. A plurality of bit lines BL may be electrically connected to the page buffer 1120 through a plurality of second interconnection lines 1125 extending from the first structure 1100F to the second structure 1100S.

In the first structure 1100F, the decoder circuit 1110 and the page buffer 1120 may perform a control operation on at least one of the memory cell transistors MCT. The decoder circuit 1110 and the page buffer 1120 may be controlled by the logic circuit 1130.

The semiconductor device 1100 may communicate with the controller 1200 through an input/output (I/O) pad 1101, which is electrically connected to the logic circuit 1130. The I/O pad 1101 may be electrically connected to the logic circuit 1130 through an I/O interconnection line 1135 extending from the first structure 1100F to the second structure 1100S.

The controller 1200 may include a processor 1210, a NAND controller 1220, and a host interface 1230. In some implementations, the electronic system 1000 may include a plurality of semiconductor devices 1100. In this case, the controller 1200 may control the semiconductor devices 1100.

The processor 1210 may generally control the operations of the electronic system 1000 including the controller 1200. The processor 1210 may operate according to certain firmware and may control the NAND controller 1220 to access the semiconductor device 1100. The NAND controller 1220 may include a NAND interface 1221 communicating with the semiconductor device 1100. A control command for controlling the semiconductor device 1100, data to be written to the memory cell transistors MCT of the semiconductor device 1100, data read from the memory cell transistors MCT of the semiconductor device 1100, and/or the like may be transmitted through the NAND interface 1221. The host interface 1230 may provide a function for communication between the electronic system 1000 and an external host. When receiving a control command from an external host through the host interface 1230, the processor 1210 may control the semiconductor device 1100 in response to the control command.

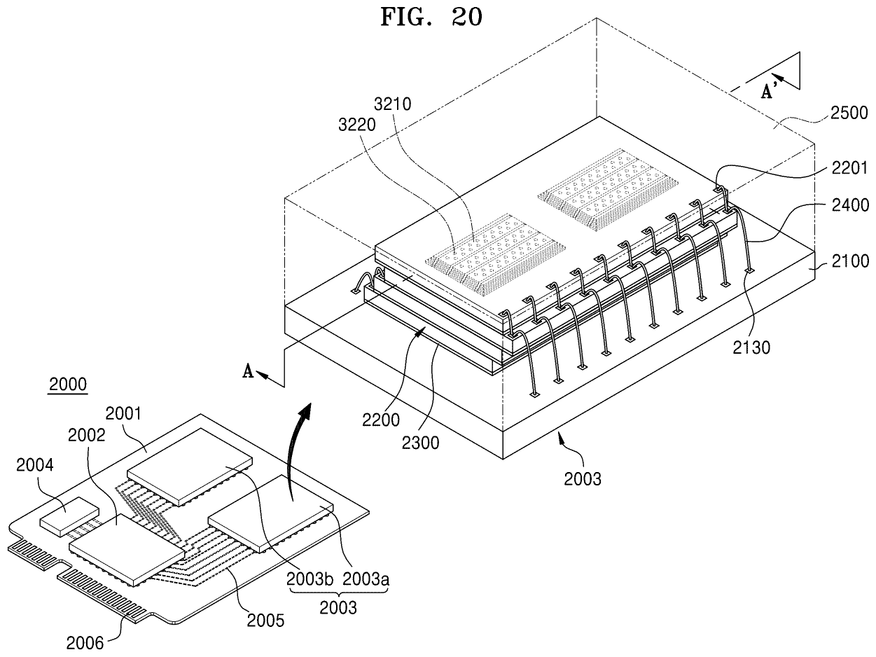

FIG. 20 is a perspective view of an example of an electronic system including a semiconductor device.

Referring to FIG. 20, an electronic system 2000 may include a main board 2001, a controller 2002 mounted on the main board 2001, at least one semiconductor package 2003, and dynamic random access memory (DRAM) 2004.

The main board 2001 may include a connector 2006, which includes a plurality of pins coupled to an external host. The number and placement of pins in the connector 2006 may vary with a communication interface between the electronic system 2000 and the external host. In some implementations, the electronic system 2000 may communicate with an external host according to any one of interfaces, such as USB, peripheral component interconnect express (PCI-Express), serial advanced technology attachment (SATA), and M-PHY for universal flash storage (UFS). In some implementations, the electronic system 2000 may be driven by electric power supplied from an external host through the connector 2006. The electronic system 2000 may further include a power management integrated circuit (PMIC), which distributes electric power supplied from the external host to the controller 2002 and the semiconductor package 2003. The semiconductor package 2003 and the DRAM 2004 may be connected to the controller 2002 by a plurality of wiring patterns 2005 formed on the main board 2001.

The controller 2002 may write data to or read data from the semiconductor package 2003 and may increase the operating speed of the electronic system 2000.

The DRAM 2004 may function as a buffer memory for mitigating the speed difference between an external host and the semiconductor package 2003 that is a data storage space. The DRAM 2004 included in the electronic system 2000 may also operate as a sort of cache memory and provide a space for temporarily storing data in a control operation on the semiconductor package 2003. When the DRAM 2004 is included in the electronic system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b separated from each other. Each of the first and second semiconductor packages 2003a and 2003b may include a plurality of semiconductor chips 2200. Each of the first and second semiconductor packages 2003a and 2003b may include a package substrate 2100, the semiconductor chips 2200 on the package substrate 2100, an adhesive layer 2300 on the bottom surface of each of the semiconductor chips 2200, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may include a printed circuit board (PCB) including a plurality of package upper pads 2130. Each of the semiconductor chips 2200 may include an I/O pad 2201. The I/O pad 2201 may correspond to an I/O pad 1101 in FIG. 19. Each of the semiconductor chips 2200 may include a plurality of gate stacks 3210 and a plurality of channel structures 3220. The semiconductor chips 2200 may include at least one of the semiconductor devices 100, 200, 300, and 400 described with reference to FIGS. 2 to 10.

In some implementations, the connection structure 2400 may include a bonding wire, which electrically connects the I/O pad 2201 to a package upper pad 2130. Accordingly, in the first and second semiconductor packages 2003a and 2003b, the semiconductor chips 2200 may be electrically connected to each other by a bonding wire and electrically connected to the package upper pads 2130 of the package substrate 2100. In some implementations, in the first and second semiconductor packages 2003a and 2003b, the semiconductor chips 2200 may be electrically connected to each other by a connection structure, which includes a through silicon via (TSV), instead of the connection structure 2400 using a bonding wire.

In some implementations, the controller 2002 and the semiconductor chips 2200 may be included in a single package. In some implementations, the controller 2002 and the semiconductor chips 2200 may be mounted on an interposer board separate from the main board 2001 and may be connected to each other by wiring formed on the interposer board.

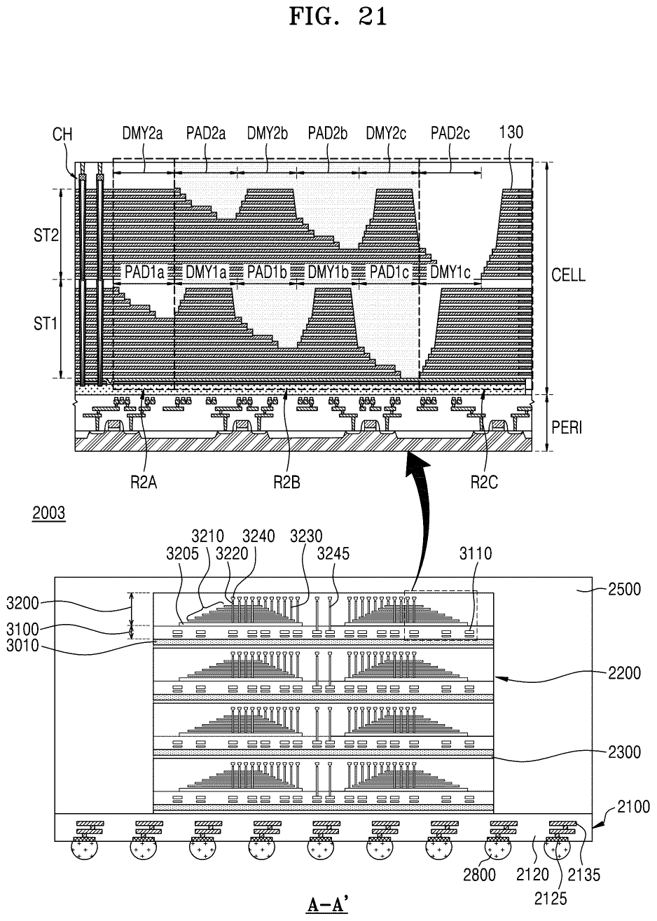

FIG. 21 is a cross-sectional view of an example of a semiconductor package including a semiconductor device.

In detail, FIG. 21 shows in detail the configurations of a cross-section taken along line A-A′ in FIG. 20.

Referring to FIG. 21, in the semiconductor package 2003, the package substrate 2100 may be a PCB.

The package substrate 2100 may include a body 2120, a plurality of upper pads (2130 in FIG. 20) on the top surface of the body 2120, a plurality of lower pads 2125 arranged on or exposed by the bottom surface of the body 2120, and a plurality of internal wirings 2135, which are inside the body 2120 and electrically connect the package upper pads 2130 to the lower pads 2125. The upper pads 2130 may be electrically connected to a plurality of connection structures 2400 (in FIG. 20). The lower pads 2125 may be respectively connected to the wiring patterns 2005 on the main board 2001 of the electronic system 2000 of FIG. 20 through a plurality of conductive connectors 2800.

Each of the semiconductor chips 2200 may include a semiconductor substrate 3010 and a first semiconductor structure 3100 and a second semiconductor structure 3200 sequentially stacked on the semiconductor substrate 3010. The first semiconductor structure 3100 may include a peripheral circuit region including peripheral wirings 3110. The second semiconductor structure 3200 may include a common source line 3205, a gate stack 3210 on the common source line 3205, channel structures 3220 passing through the gate stack 3210, bit line 3240 respectively and electrically connected to the channel structures 3220, and contact plugs 3230 respectively and electrically connected to word lines of the gate stack 3210.

As described above with reference to FIGS. 2 to 10, in each of the semiconductor chips 2200, the first pad regions PAD1a, PAD1b, and PAD1c and the second pad regions PAD2a, PAD2b, and PAD2c may be shifted from each other and may thus not overlap each other in the vertical direction Z.

Each of the semiconductor chips 2200 may include a through wiring 3245, which is electrically connected to the peripheral wirings 3110 of the first semiconductor structure 3100 and extends into the second semiconductor structure 3200. The through wiring 3245 may be outside the gate stack 3210 and may be further provided to pass through the gate stack 3210. Each of the semiconductor chips 2200 may further include an I/O pad (2201 in FIG. 20), which is electrically connected to the peripheral wirings 3110 of the first semiconductor structure 3100.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A semiconductor device comprising:
a substrate having an extension region and a cell region, the extension region having a first region, a second region, and a third region, the first region being closest to the cell region in a first horizontal direction, the third region being farthest from the cell region, and the second region being between the first region and the third region;
a plurality of gate electrodes separated from each other on the substrate in a vertical direction, the plurality of gate electrodes defining a first stack structure and a second stack structure;
a plurality of isolation regions passing through the first stack structure and the second stack structure in the vertical direction, the plurality of isolation regions extending in the first horizontal direction;
a plurality of channel structures passing through the first stack structure and the second stack structure in the vertical direction in the cell region; and
a plurality of first contact plugs and a plurality of second contact plugs passing through the first stack structure and the second stack structure in the vertical direction in the extension region,
wherein the first stack structure includes a plurality of first pad regions and a plurality of first dummy regions in the extension region, each of the plurality of gate electrodes is connected with a respective first contact plug of the plurality of first contact plugs in each of the plurality of first pad regions, and each of the plurality of first dummy regions is at a side of a respective first pad region of the plurality of first pad regions and is separated from the plurality of first contact plugs,
wherein the second stack structure includes a plurality of second pad regions and a plurality of second dummy regions in the extension region, each of the plurality of gate electrodes is connected with a respective second contact plug of the plurality of second contact plugs in each of the plurality of second pad regions, and each of the plurality of second dummy regions is at a side of a respective second pad region of the plurality of second pad regions and is separated from the plurality of second contact plugs,
wherein the plurality of first pad regions overlap the plurality of second dummy regions in the vertical direction, and the plurality of second pad regions overlap the plurality of first dummy regions in the vertical direction, and
wherein the plurality of isolation regions include a word line cut and a dummy line cut, the word line cut continuously extending in the first horizontal direction in the cell region and the extension region, and the dummy line cut discontinuously extending in the first region and the third region of the extension region and continuously extending in the second region of the extension region.

2. The semiconductor device of claim 1, wherein
the first region of the extension region includes a region from a start of the extension region to a start of the plurality of first dummy regions,
the second region of the extension region includes a region from the start of the plurality of first dummy regions to an end of the plurality of second dummy regions, and
the third region of the extension region includes a region from the end of the plurality of second dummy regions to an end of the extension region.

3. The semiconductor device of claim 2, wherein, in each of the first region and the third region of the extension region,
the dummy line cut includes a plurality of dummy line parts and a plurality of pad connection parts alternately arranged with the plurality of dummy line parts in the first horizontal direction,
the plurality of dummy line parts include a dielectric material separating the plurality of gate electrodes from each other in a second horizontal direction that crosses the first horizontal direction, and
the plurality of pad connection parts connect the plurality of gate electrodes with each other in the second horizontal direction.

4. The semiconductor device of claim 3, wherein, in each of the first region and the third region of the extension region,
a pad connection part of the plurality of pad connection parts and the plurality of gate electrodes around the pad connection part have an H or I shape in a plan view.

5. The semiconductor device of claim 4, wherein, in the second region of the extension region,
each of the plurality of dummy line parts extends as a single line in the first horizontal direction, and the plurality of pad connection parts are outside the second region.

6. The semiconductor device of claim 1, wherein, in the first stack structure and the second stack structure,
the plurality of gate electrodes in the plurality of first pad regions and the plurality of second pad regions have a stepped structure having a height decreasing away from the cell region in the first horizontal direction, and
the plurality of first pad regions include a flat region at a bottom of the plurality of first pad regions, and the plurality of second pad regions include a flat region at a bottom of the plurality of second pad regions.

7. The semiconductor device of claim 6, wherein, in the first stack structure and the second stack structure,
the plurality of first dummy regions have a plurality of first protrusions and the plurality of second dummy regions have a plurality of second protrusions, more gate electrodes are stacked in the plurality of first dummy regions and the plurality of second dummy regions than in the plurality of first pad regions and the plurality of second pad regions, and the plurality of first protrusions and the plurality of second protrusions have equal maximum heights.

8. The semiconductor device of claim 7, wherein
the first region of the extension region includes a region from a start of the extension region to an end of a first pad region that is first among the plurality of first pad regions,
the second region of the extension region includes a region from the end of the first pad region to a start of a second pad region that is last among the plurality of second pad regions, and
the third region of the extension region includes a region from the start of the second pad region to an end of the extension region.

9. The semiconductor device of claim 1, comprising:
a third stack structure on the second stack structure; and
a plurality of third contact plugs passing through the third stack structure in the vertical direction in the extension region,
wherein the third stack structure includes a plurality of third pad regions and a plurality of third dummy regions in the extension region, each of the plurality of gate electrodes is connected with a respective third contact plug of the plurality of third contact plugs in each of the plurality of third pad regions, and each of the plurality of third dummy regions is at a side of a respective third pad region of the plurality of third pad regions and is separated from the plurality of third contact plugs.

10. The semiconductor device of claim 9, wherein
the first region of the extension region includes a region from a start of the extension region to a start of the plurality of first dummy regions,
the second region of the extension region includes a region from the start of the plurality of first dummy regions to an end of the plurality of third dummy regions, and
the third region of the extension region includes a region from an end of the plurality of third dummy regions to an end of the extension region.

11. A semiconductor device comprising:
a memory cell structure on a peripheral circuit structure,
wherein the peripheral circuit structure includes:
a first substrate;
a plurality of circuit elements on the first substrate; and
a plurality of lower wiring lines connected with the plurality of circuit elements, and
wherein the memory cell structure includes:
a second substrate having an extension region and a cell region, the extension region having a first region, a second region, and a third region, the first region being closest to the cell region in a first horizontal direction, the third region being farthest from the cell region, and the second region being between the first region and the third region;
a plurality of gate electrodes separated from each other on the second substrate in a vertical direction, the plurality of gate electrodes defining a first stack structure and a second stack structure;
a plurality of interlayer dielectric layers alternately stacked with the plurality of gate electrodes;
a plurality of isolation regions passing through the first stack structure and the second stack structure in the vertical direction, the plurality of isolation regions extending in the first horizontal direction;
a plurality of channel structures passing through the first stack structure and the second stack structure in the vertical direction in the cell region;
a plurality of first contact plugs and a plurality of second contact plugs passing through the first stack structure and the second stack structure in the vertical direction in the extension region, extending into the peripheral circuit structure, and connected with the plurality of lower wiring lines; and
a plurality of dummy extension structures passing through the first stack structure and the second stack structure in the vertical direction in the extension region,
wherein the first stack structure includes a plurality of first pad regions and a plurality of first dummy regions in the extension region, each of the plurality of gate electrodes is connected with a respective first contact plug of the plurality of first contact plugs in each of the plurality of first pad regions, and each of the plurality of first dummy regions is at a side of a respective first pad region of the plurality of first pad regions and is separated from the plurality of first contact plugs,
wherein the second stack structure includes a plurality of second pad regions and a plurality of second dummy regions in the extension region, each of the plurality of gate electrodes is connected with a respective second contact plug of the plurality of second contact plugs in each of the plurality of second pad regions, and each of the plurality of second dummy regions is at a side of a respective second pad region of the plurality of second pad regions and is separated from the plurality of second contact plugs,
wherein the plurality of first pad regions overlap the plurality of second dummy regions in the vertical direction, and the plurality of second pad regions overlap the plurality of first dummy regions in the vertical direction, and
wherein the plurality of isolation regions include a word line cut and a dummy line cut, the word line cut continuously extending in the first horizontal direction in the cell region and the extension region, and the dummy line cut discontinuously extending in at least one of the first region or the third region of the extension region and continuously extending in the second region of the extension region.

12. The semiconductor device of claim 11, wherein
the first region of the extension region includes a region from a start of the extension region to a start of the plurality of first dummy regions,
the second region of the extension region includes a region from the start of the plurality of first dummy regions to an end of the plurality of second dummy regions, and
the third region of the extension region includes a region from the end of the plurality of second dummy regions to an end of the extension region.

13. The semiconductor device of claim 12, wherein, in the first region of the extension region,
the dummy line cut includes a plurality of dummy line parts and a plurality of pad connection parts alternately arranged with the plurality of dummy line parts in the first horizontal direction,
the plurality of dummy line parts include a dielectric material separating the plurality of gate electrodes from each other in a second horizontal direction that crosses the first horizontal direction, and
the plurality of pad connection parts connect the plurality of gate electrodes with each other in the second horizontal direction.

14. The semiconductor device of claim 13, wherein, in the first region of the extension region,
a pad connection part of the plurality of pad connection parts and the plurality of gate electrodes around the pad connection part have an H or I shape in a plan view.

15. The semiconductor device of claim 14, wherein, in the second region and the third region of the extension region,
each of the plurality of dummy line parts extends as a single line in the first horizontal direction, the plurality of pad connection part being outside the second region and the third region, and
each of the plurality of dummy line parts extends in the second horizontal direction and cuts a portion of each of the plurality of dummy extension structures adjacent to each other.

16. The semiconductor device of claim 12, wherein, in the third region of the extension region,
the dummy line cut includes a plurality of dummy line parts and a plurality of pad connection parts alternately arranged with the plurality of dummy line parts in the first horizontal direction,
the plurality of dummy line parts include a dielectric material separating the plurality of gate electrodes from each other in a second horizontal direction that crosses the first horizontal direction, and
the plurality of pad connection parts connect the plurality of gate electrodes with each other in the second horizontal direction.

17. The semiconductor device of claim 16, wherein, in the third region of the extension region,
a pad connection part of the plurality of pad connection parts and the plurality of gate electrodes around the pad connection part have an H or I shape in a plan view.

18. The semiconductor device of claim 17, wherein, in the first region and the second region of the extension region,
each of the plurality of dummy line parts extends as a single line in the first horizontal direction, the plurality of pad connection part being outside the first region and the second region, and
each of the plurality of dummy line parts extends in the second horizontal direction and cuts a portion of each of the plurality of dummy extension structures adjacent to each other.

19. An electronic system comprising:
a main substrate;
a semiconductor device on the main substrate; and
a controller on the main substrate and connected with the semiconductor device,
wherein the semiconductor device includes a peripheral circuit structure and a memory cell structure on the peripheral circuit structure,
wherein the peripheral circuit structure includes
a circuit substrate, a peripheral circuit transistor on the circuit substrate, a lower wiring connected with the peripheral circuit transistor, and a peripheral dielectric layer covering the peripheral circuit transistor and the lower wiring, and
wherein the memory cell structure includes:
a memory substrate having an extension region and a cell region, the extension region having a first region, a second region, and a third region, the first region being closest to the cell region in a first horizontal direction, the third region being farthest from the cell region, and the second region being between the first region and the third region;
a plurality of gate electrodes separated from each other on the memory substrate in a vertical direction, the plurality of gate electrodes defining a first stack structure and a second stack structure;
a plurality of isolation regions passing through the first stack structure and the second stack structure in the vertical direction, the plurality of isolation regions extending in the first horizontal direction;
a plurality of channel structures passing through the first stack structure and the second stack structure in the vertical direction in the cell region; and
a plurality of first contact plugs and a plurality of second contact plugs passing through the first stack structure and the second stack structure in the vertical direction in the extension region,
wherein the first stack structure includes a plurality of first pad regions and a plurality of first dummy regions in the extension region, each of the plurality of gate electrodes is connected with a respective first contact plug of the plurality of first contact plugs in each of the plurality of first pad regions, and each of the plurality of first dummy regions is at a side of a respective first pad region of the plurality of first pad regions and is separated from the plurality of first contact plugs,
wherein the second stack structure includes a plurality of second pad regions and a plurality of second dummy regions in the extension region, each of the plurality of gate electrodes is connected with a respective second contact plug of the plurality of second contact plugs in each of the plurality of second pad regions, and each of the plurality of second dummy regions is at a side of a respective second pad region of the plurality of second pad regions and is separated from the plurality of second contact plugs,
wherein the plurality of first pad regions overlap the plurality of second dummy regions in the vertical direction, and the plurality of second pad regions overlap the plurality of first dummy regions in the vertical direction, and
wherein the plurality of isolation regions include a word line cut and a dummy line cut, the word line cut continuously extending in the first horizontal direction in the cell region and the extension region, and the dummy line cut discontinuously extending in the first region and the third region of the extension region and continuously extending in the second region of the extension region.

20. The electronic system of claim 19, wherein
the main substrate includes a plurality of wiring patterns electrically connecting the semiconductor device with the controller,
the first region of the extension region is from a start of the extension region to a start of the plurality of first dummy regions,
the second region of the extension region is from the start of the plurality of first dummy regions to an end of the plurality of second dummy regions, and
the third region of the extension region is from the end of the plurality of second dummy regions to an end of the extension region.
